(19) United States
(12) Patent Application Publication
(10) Pub. No.: US 2024/0407168 A1
(43) Pub. Date: Dec. 5, 2024

(54) SEMICONDUCTOR DEVICE AND FABRICATION METHOD THEREOF, MEMORY SYSTEM

(71) Applicant: YANGTZE MEMORY TECHNOLOGIES CO., LTD., Wuhan (CN)

(72) Inventors: Quan Zhang, Wuhan (CN); Lei Xue, Wuhan (CN); Yanwei Shi, Wuhan (CN); Wenshan Xu, Wuhan (CN); Chao Sun, Wuhan (CN); Liang Chen, Wuhan (CN); Boru Xie, Wuhan (CN)

(21) Appl. No.: 18/378,513

(22) Filed: Oct. 10, 2023

Related U.S. Application Data
(63) Continuation of application No. PCT/CN23/97606, filed on May 31, 2023.

(51) Int. Cl. H10B 43/35; H01L 25/065; H01L 29/66; H01L 29/78; H10B 41/20; H10B 41/35; H10B 43/20

(52) U.S. Cl. CPC H10B 43/35; H01L 25/0657; H01L 29/66795; H01L 29/7851; H10B 41/20; H10B 41/35; H10B 43/20

(57) ABSTRACT

The present disclosure provides a semiconductor device and a manufacturing method thereof, as well as a memory system. The semiconductor device includes a first semiconductor structure comprising a first well region and transistors in the first well region, and a second semiconductor structure bonded with the first semiconductor structure and including a second well region, and fin field effect transistors in the second well region. Each fin field effect transistor includes a fin structure, a gate oxide layer in contact with a top surface and side surfaces of the fin structure, and a gate layer covering the gate oxide layer.

### CROSS-REFERENCE TO RELATED APPLICATIONS

This application is a continuation of International Application No. PCT/CN2023/097606, filed on May 31, 2023, the content of which is incorporated herein by reference in its entirety.

### TECHNICAL FIELD

The present application is related to the semiconductor technology field, in particular to a semiconductor device and a fabrication method thereof, as well as a memory system.

### BACKGROUND

As the feature sizes of memory chips approach the lower limit of process, planar process and manufacturing techniques have become challenging and expensive, resulting in storage density of 2D or planar NAND flash memories approaching the upper limit. In order to overcome limitations on 2D or planar NAND flashes, memory chips with three-dimensional structure (3D NAND) have been developed in the industry, which improve the storage density by arranging memory cells on the substrate in three dimensions.

In current 3D memories, the integration level of transistors is still low, which causes memory chips still suffer large area, and prior art manufacturing process is relatively cumbersome and expensive.

### SUMMARY

Examples of the present disclosure provide a semiconductor device and a manufacturing method thereof as well as a memory system that can improve transistor performance while reducing chip area.

The present disclosure provides a semiconductor device comprising: a first semiconductor structure comprising a first well region; and a second semiconductor structure bonded with the first semiconductor structure and comprising a second well region, wherein the second well region of the second semiconductor structure has a fin field effect transistor disposed therein.

In an optional example, the first semiconductor structure comprises a first insulating layer; the second semiconductor structure comprises a second insulating layer, a side of which is bonded with the first insulating layer; an active layer disposed on a side of the second insulating layer away from the first semiconductor structure, the active layer of the second well region comprises at least one fin; a gate oxide layer disposed on the fin; and a gate layer disposed on the gate oxide layer.

In an optional example, the fin has a thickness of 30 nm-65 nm in Z direction, wherein the Z direction is a direction perpendicular to a plane where the second insulating layer extends.

In an optional example, the fin comprises a top surface and side surfaces, the top surface being parallel to the plane where the second insulating layer extends, the side surfaces being connected with the top surface, and the gate oxide layer covering the top surface and the side surfaces.

In an optional example, the second insulating layer comprises at least one protruding portion protruding away from a side of the first semiconductor structure, the at least one fin being disposed correspondingly on the at least one protruding portions respectively.

In an optional example, a width of a contact surface between the protruding portion and the fin in X direction is equal to a width of a contact surface between the fin and the protruding portion in the X direction, the X direction being a direction along which the at least one fin is arranged.

In an optional example, a width of a contact surface between the protruding portion and the fin in X direction is smaller than a width of a contact surface between the fin and the protruding portion in the X direction, the fin further comprises a top surface, side surfaces and a bottom surface, the bottom surface being a non-contact surface of the fin that suspends beyond the contact surface of the protruding portion, the gate oxide layer covering the top surface, the side surfaces and the bottom surface, the X direction being a direction along which the at least one fin are arranged.

In an optional example, the second well region comprises a first sub-well region and a second sub-well region, and a thickness of the gate oxide layer in the first sub-well region is greater than a thickness of the gate oxide layer in the second sub-well region.

In an optional example, the second semiconductor structure further comprises a first isolation structure being configured to isolate the gate layer corresponding to two adjacent fins.

In an optional example, the second semiconductor structure further comprises a second isolation structure being configured to isolate the gate layer corresponding to different well regions.

In an optional example, the first semiconductor structure of the first well region has planar transistors disposed thereon.

In an optional example, a thickness of the gate oxide layer of the planar transistor is greater than a thickness of the gate oxide layer of the fin field effect transistor.

In an optional example, the semiconductor device further comprises a memory array structure bonded with the second semiconductor structure.

The present disclosure further provides a method of manufacturing a semiconductor device, comprising: providing a first semiconductor structure comprising a first well region and a second semiconductor structure comprising a second well region; bonding the first semiconductor structure with the second semiconductor structure; and forming a fin field effect transistor in the second well region of the second semiconductor structure.

In an optional example, the first semiconductor structure comprises a first insulating layer, and the second semiconductor structure an active layer; bonding the first semiconductor structure with the second semiconductor structure comprises: forming a second insulating layer on the active layer; and bonding the second insulating layer with the first insulating layer such that the first semiconductor structure is bonded with the second semiconductor structure.

In an optional example, forming the fin field effect transistor in the second well region of the second semiconductor structure comprises: forming at least one groove on the active layer that exposes the second insulating layer at bottom and isolates the active layer into at least one fin; forming a gate oxide layer on the at least one fin; and forming a gate layer on the gate oxide layer.

In an optional example, before forming the at least one groove on the active layer, the method further comprises: thinning the active layer.

In an optional example, before forming the gate oxide layer on the at least one fin, the method further comprises: forming a liner layer on the at least one fin; and removing the liner layer.

In an optional example, the fin comprises a top surface and side surfaces, the top surface being parallel to a plane where the second insulating layer extends, the side surfaces being connected with the top surface; forming the gate oxide layer on the at least one fin comprises: forming the gate oxide layer on the top surface and side surfaces of the at least one fin.

In an optional example, forming the at least one groove on the active layer comprises: forming at least one groove on the active layer that isolates the active layer into at least one fin and exposes the second insulating layer at the bottom and makes the second insulating layer to form at least one protruding portions that protrude away from a side of the first semiconductor structure and correspond to the at least one fin.

In an optional example, a width of a contact surface between the protruding portion and the fin in X direction is smaller than a width of a contact surface between the fin and the protruding portion in the X direction, the fin further comprises a top surface, side surfaces and a bottom surface, the bottom surface being a non-contact surface of the fin that suspends beyond a contact surface of the protruding portion, the X direction being a direction along which the at least one fin is arranged; forming the gate oxide layer on the at least one fin comprises forming the gate oxide layer on the top surface, side surfaces and bottom surface of the at least one fin.

In an optional example, forming the gate layer on the gate oxide layer comprises: forming the gate layer on the gate oxide layer and the exposed second insulating layer; thinning the gate layer to expose a top surface of the gate oxide layer that is parallel to the plane where the second insulating layer extends.

In an optional example, after forming the gate layer on the gate oxide layer, the method further comprises: forming a first isolation structure on the second insulating layer to isolate the gate layer corresponding to two adjacent fins.

In an optional example, after forming the gate layer on the gate oxide layer, the method further comprises: forming a second isolation structure on the gate oxide layer to isolate the gate layer corresponding to different well regions.

In an optional example, the method further comprises: providing a memory array structure; and bonding the memory array structure with the second semiconductor structure.

The present disclosure further provides a memory system comprising a semiconductor device and a controller coupled to the semiconductor device to control the semiconductor device to store data, the semiconductor device being the semiconductor device as described above, or the semiconductor device being the semiconductor device manufactured by the manufacturing method as described above.

The present disclosure provides a semiconductor device comprising: a first semiconductor structure comprising a first well region; and a second semiconductor structure bonded with the first semiconductor structure and comprising a second well region, wherein the second well region of the second semiconductor structure has a fin field effect transistor disposed therein. In the above way, by disposing the first well region and the second well region on the two semiconductor structures such as wafers respectively and providing fin field effect transistors in the second well region of the second semiconductor structure, the way of the examples of the present disclosure can improve transistor performance using fin field effect transistors while reducing chip area.

### BRIEF DESCRIPTION OF ACCOMPANYING DRAWINGS

In order to explain the technical solutions in examples of the present disclosure more clearly, accompanying drawings required in describing the examples will be described in brief below. It is obvious that the drawings described below are only some examples of the present disclosure and other drawings may be obtained according to these drawings without any creative work for those skilled in the art.

FIG. 1 is a structural diagram of a first example of a semiconductor device provided by the present disclosure;

FIG. 2 is a structural diagram of a second example of a semiconductor device provided by the present disclosure;

FIG. 3 is a structural diagram of a first example of the second semiconductor structure 20;

FIG. 4 is a partial diagram of a fin in FIG. 3;

FIG. 5 is a structural diagram of a second example of the second semiconductor structure 20;

FIG. 6 is a structural diagram of a third example of the second semiconductor structure 20;

FIG. 7 is a partial diagram of a fin in FIG. 6;

FIG. 8 is a structural diagram of a fourth example of the second semiconductor structure 20;

FIG. 9 is a structural diagram of a fifth example of the second semiconductor structure 20;

FIG. 10 is a flow chart of an example of a manufacturing method of a semiconductor device provided in the present disclosure;

FIG. 11 is a structural diagram of an example of step 102 in FIG. 10;

FIG. 12 is a flow chart of a first example of step 103 in FIG. 10;

FIG. 13 is a structural diagram of an example of step 1031 in FIG. 12;

FIG. 14 is a structural diagram of an example of step 1032 in FIG. 12;

FIG. 15 is a flow chart of a second example of step 103 in FIG. 10;

FIG. 16 is a structural diagram of an example of step 103a in FIG. 15;

FIG. 17 is a structural diagram of an example of step 103b in FIG. 15; and

FIG. 18 is a structural diagram of an example of a memory system provided in the present disclosure.

### DETAILED DESCRIPTION

The technical solution in examples of the present disclosure will be described below clearly and completely with reference to accompanying drawings in examples of the present disclosure. However, it is obvious that the described examples are only parts of the examples rather than all examples of the present disclosure. Based on the examples of the present disclosure, all other examples obtained by those skilled in the art without any creative work fall within the scope of the present disclosure.

In the description of the disclosure, it is understood that orientation and position relationships indicated by terms “center”, “longitudinal”, “traverse”, “length”, “width”, “thickness”, “upper”, “lower”, “front”, “back”, “left”, “right”, “vertical”, “horizontal”, “top”, “bottom”, “inner” and “outer” are those based on the drawings and only for the purpose of facilitating and simplifying the description of the present disclosure. There is no indication or implication that the devices or elements as referred to must have any particular orientations and positions, or be constructed or operated in any particular orientations and positions. As a result, they should not be understood as any limitation to the present disclosure. Moreover, the terms “first”, “second” etc. are only used for the purpose of description and should not be understood to indicate or imply relative importance or to designate the number of the referenced technical features implicitly. Therefore, features defined with “first” and “second” may explicitly or implicitly include one or more said features. In the description of the present disclosure, “a plurality of” means two or more unless otherwise specified.

“A and/or B” includes the following three combinations: only A, only B and combination of A and B.

The use of “adapted to” or “configured to” in the present disclosure implies open and inclusive wording but not excluding apparatuses adapted to or configured to execute additional tasks or steps. In addition, the use of “based on” implies open and inclusive wording, since a process, a step, a computation or other acts “based on” one or more said conditions or values may be based on additional conditions or values other than said value in practice.

In the present disclosure, the term “exemplary” is used to represent “used as an example, illustration or description”. Any example described as “exemplary” in the present disclosure is not necessarily interpreted as more preferable or more advantageous over other examples. In order for those skilled in the art to implement and use the present disclosure, the following description is given. In the following description, details are listed for the purpose of explanation. It should be understood that those of ordinary skill in the art may appreciate that the present disclosure may be implemented without these specific details. In other examples, well known structures and processes will not be described in detail to prevent unnecessary details from confusing the description of the present disclosure. Accordingly, the present disclosure is not intended to be limited to the illustrated examples, but consistent with the broadest scope conforming to the principles and features disclosed in the present disclosure.

Referring to FIG. 1, which is a structural diagram of a first example of the semiconductor device provided in the present disclosure, the semiconductor device 100 includes a first semiconductor structure 10 and a second semiconductor structure 20 bonded with the first semiconductor structure 10. The first semiconductor structure 10 includes a first well region, and the second semiconductor structure 20 includes a second well region with fin field effect transistors disposed therein.

Optionally, the first semiconductor structure 10 and the second semiconductor structure 20 may be wafers. A wafer refers to a silicon wafer used in manufacturing silicon semiconductor circuits, and its original material is silicon. High purity poly-crystalline silicon is dissolved and mixed with seeds of silicon crystal, and then pulled out slowly to form the single crystalline silicon of cylindrical shape. The silicon crystal bar is ground, polished and sliced to form silicon wafer, namely the wafer.

In an example, the first well region is a high voltage (HV) well region and the second well region is a low voltage well region. Further, the low voltage well region may further include a first sub-well region and a second sub-well region. For example, the first sub-well region is the LV (Low Voltage) well region, and the second sub-well region is the LLV (Low Low Voltage) well region. Optionally, in an example, the first well region (the high voltage well region HV) may be understood as a region in which semiconductor devices formed therein have turn-on voltages or threshold voltages greater than 5V, the second well region (the low voltage well region LV and the low low voltage well region LLV) may be understood as a region in which semiconductor devices formed therein have turn-on voltages or threshold voltages smaller than or equal to 5V; wherein the low low voltage well region LLV may be understood as a region in which semiconductor devices formed therein have turn-on voltages or threshold voltages smaller than or equal to 1.6V.

Further, the first well region of the first semiconductor structure 10 has planar transistors disposed therein, and the second well region of the second semiconductor structure 20 has fin field effect transistors disposed therein.

The fin field effect transistor is a novel complementary metal oxide semiconductor transistor. In traditional transistor structures, the gate which controls the current flowing through can only control turning-on and turning-off of the circuits on a side of the gate, which belongs to a planar architecture. In a Fin-FET architecture, the gate is in the form of fin-like fork-shaped 3D architecture and can control turning-on and turning-off of the circuits on both sides of the circuits. Such design can significantly improve circuit control and reduce leakage, and also significantly reduce the gate length of the transistor. The Fin-FET is different from the planar MOSFET mainly in that its channel is formed by high and thin fin projected from the insulating substrate with source and drain on either side thereof and a gate abutting its sidewall and top in order to assist in controlling the current. Such a fin-like structure increases the area of channel surrounded by the gate, enhances control on the channel by the gate, thereby effectively mitigating the short channel effect in planar devices, significantly improving circuit control and reducing leakage, and greatly reducing gate length of the transistor. Exactly for this characteristic, a Fin-FET does not need a highly doped channel, thereby effectively reducing the impurity ion scattering effect and improving channel charge-carrier mobility.

Fin-FET devices are obviously advantageous over traditional planar transistor. First of all, Fin-FET channel is lightly doped or even undoped, which avoid scattering effects of discrete doping atoms. The carrier mobilities would be increased significantly as compared to heavily doped planar devices. In addition, as compared to traditional planar CMOS, FinFET devices have absolute advantages in terms of suppressing sub-threshold current and gate leakage. The bulk fin structure such as dual-gate or half-around gate of a Fin-FET increases the control area of the gate to the channel such that the ability of gate control is greatly enhanced. As a result, short channel effects can be suppressed effectively and sub-threshold leakage current is reduced. Since the short channel effect is suppressed and the gate control capability is enhanced, the Fin-FET device can use a thicker gate oxide than traditional devices such that the gate leakage of Fin-FET device can also be reduced. Obviously, the Fin-FET is advantageous over PDSOI. Further, since Fin-FET is similar to CMOS in process, it is easy to implement in technology sense and applied broadly in manufacturing small ICs.

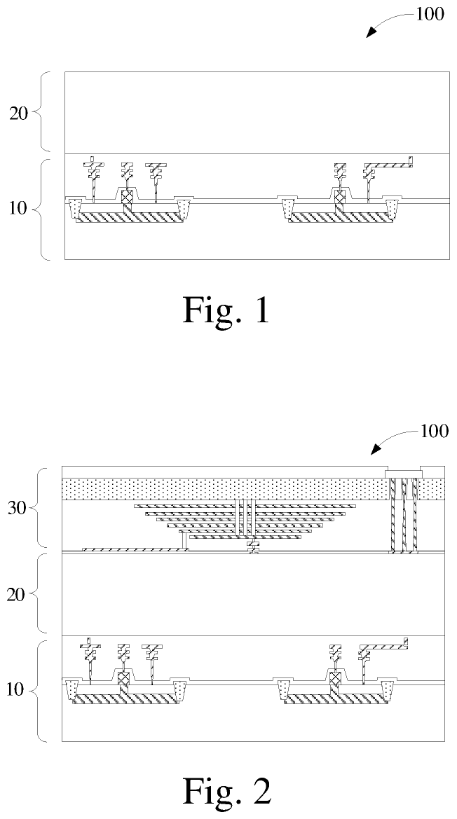

Referring to FIG. 2, which is a structural diagram of a second example of the semiconductor device provided in the present disclosure, the semiconductor device 100 includes a first semiconductor structure 10, a second semiconductor structure 20 and a memory array structure 30. The first semiconductor structure 10 is bonded with the second semiconductor structure 20, and the memory array structure 30 is connected with the second semiconductor structure 20. The first semiconductor structure 10 includes a first well region, and the second semiconductor structure 20 includes a second well region with fin field effect transistors disposed therein.

Optionally, either the memory array structure 30 and the second semiconductor structure 20 may be connected by bonding, or the memory array structure 30 may be formed on the second semiconductor structure 20 by deposition process.

It is noted that, in this example, the first well region is the high voltage well region, and the second well region is the low voltage well region. Therefore, the first semiconductor structure 10, the second semiconductor structure 20 and the memory array structure 30 are stacked and bonded in this order, that is, the second semiconductor structure 20 including the low voltage well region (such as LV well region and LLV well region) is closer to the memory array structure 30 and the first semiconductor structure 10 including the high voltage well region (such as HV well region) is farther from the memory array structure 30.

Further, the first well region of the first semiconductor structure 10 has planar 30) transistors disposed therein, and the second well region of the second semiconductor structure 20 has fin field effect transistors disposed therein.

In this example, the memory array structure 30 includes several memory cells for storing data, and the first semiconductor structure 10 and the second semiconductor structure 20 serve as periphery circuits (periphery devices) of the memory array structure 30, the periphery devices including periphery circuits such as page buffers, decoders such as row decoders and column decoders, sense amplifiers, drivers such as word drivers, charge pumps, current or voltage references, at least one of which including semiconductor structures and transistors disposed on the semiconductor structures. Depending on the connection architectures between the peripheral circuits and the memory array structure 30, the peripheral circuits may be classified into periphery near cell (PNC) architectures, peripheral under cell (PUC) architectures or inverted architectures, which is not limited in examples of the present disclosure.

It is understood that the semiconductor structure to be claimed in examples of the present disclosure may be the one shown in FIG. 2 (i.e., 3D memory), or the one shown in FIG. 1 (i.e., a part of the 3D memory), which is not limited in the present disclosure.

With respect to the examples shown in FIGS. 1 and 2, the semiconductor device provided in the present disclosure includes: a first semiconductor structure including a first well region; and a second semiconductor structure bonded with the first semiconductor structure and including a second well region, wherein the second well region of the second semiconductor structure has fin field effect transistors disposed therein. In the above way, by disposing the first well region and the second well region on the two semiconductor structures such as wafers respectively and providing fin field effect transistors in the second well region of the second semiconductor structure, the way of the examples of the present disclosure can improve transistor performance using fin field effect transistors while reducing chip area.

The second semiconductor structure 20 above will be described in detail below. In the following description of examples, X, Y and Z directions are defined, wherein the X direction is the horizontal direction in the figure, the Z direction is the vertical direction in the figure, the X and Z directions form a XZ plane, the Y direction is perpendicular to the XZ plane, the X and Y directions form a XY plane, and the XY plane is the horizontal plane in the figure.

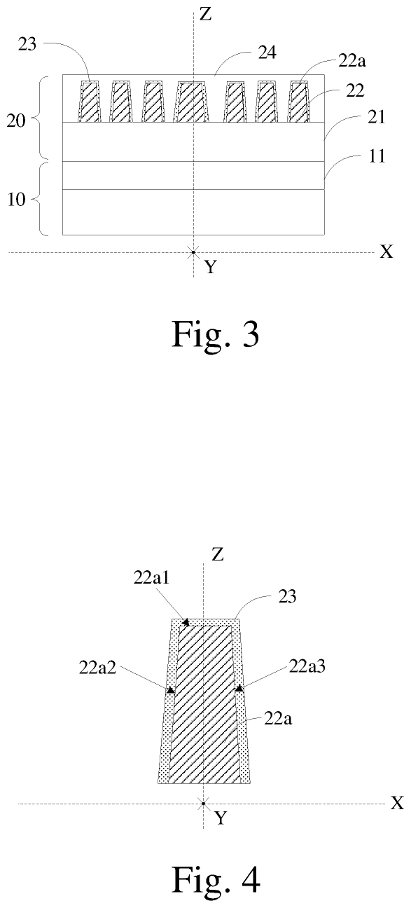

As shown in FIG. 3, which is a structural diagram of a first example of the second semiconductor structure 20. The first semiconductor structure 10 includes a first insulating layer 11, the second semiconductor structure 20 includes a second insulating layer 21, an active layer 22, a gate oxide layer 23 and a gate layer 24, wherein a side of the second insulating layer 21 is bonded with the first insulating layer 11.

The active layer 22 is disposed on a side of the second insulating layer 21 away from the first semiconductor structure 10, and the active layer 22 of the second well region includes at least one fin 22a on which the gate oxide layer 23 is disposed, and the gate layer 24 is disposed on the gate oxide layer 23.

In particular, the plane where the second insulating layer 21 extends is parallel to the XY plane. The active layer 22 is disposed on a side of the second insulating layer 21 away from the first semiconductor structure 10 and includes at least one fin 22a extending in the Y direction and having a width in X direction and a thickness in Z direction. The at least one fin 22a are arranged in X direction and have a spacing between every two fins 22a when the number of the fin 22a is multiple. The gate oxide layer 23 is disposed on the fin 22a, including disposed on a top surface (a side away from the second insulating layer 21 and parallel to the XY plane) and side surfaces (the opposite two sides based on the XZ plane) of the fin 22a in an example. The gate layer 24 is disposed on the gate oxide layer 23, and the gate layer 24 is disposed on the gate oxide layer 23 between every two fins 22a when the number of the fin 22a is multiple.

In an example, referring to FIG. 4, which is a partial diagram of the fin in FIG. 3, which is along the thickness direction (Z direction) of the fin 22a, a width of the upper end of the fin 22a in X direction is smaller than a width of the lower end in X direction due to the etch process. Further, the fin 22a includes a top surface 22al and side surfaces (a first side surface 22a2 and a second side surface 22a3), in which the first side surface 22a2 and the second side surface 22a3 are two side surfaces symmetrical about the YZ plane, the top surface 22al is parallel to the plane where the second insulating layer 21 extends, the side surfaces (the first side surface 22a2 and the second side surface 22a3) are connected with the top surface 22al, and the gate oxide layer 23 covers the top surface 22al and the side surfaces (the first side surface 22a2 and the second side surface 22a3).

As can be understood, in this example, by providing the active layer 22 as at least one fin 22a and then covering the top surface and side surfaces of the fin 22a with the gate oxide layer 23, the channel of the Fin-FET structure formed as above is mainly formed by high and thin fin projected from the insulating substrate with source and drain on either side thereof and a gate abutting its sidewalls and top for assisting in current control. Such a fin-like structure increases the area of channel surrounded by the gate, enhances the control of the gate to the channel, thereby effectively mitigating the short channel effect appeared in planar devices, significantly improving circuit control and reducing leakage, and greatly reducing gate length of the transistor. Exactly for this characteristic, a Fin-FET does not need a highly doped channel, thereby effectively reducing the impurity ion scattering effect and improving channel charge-carrier mobility.

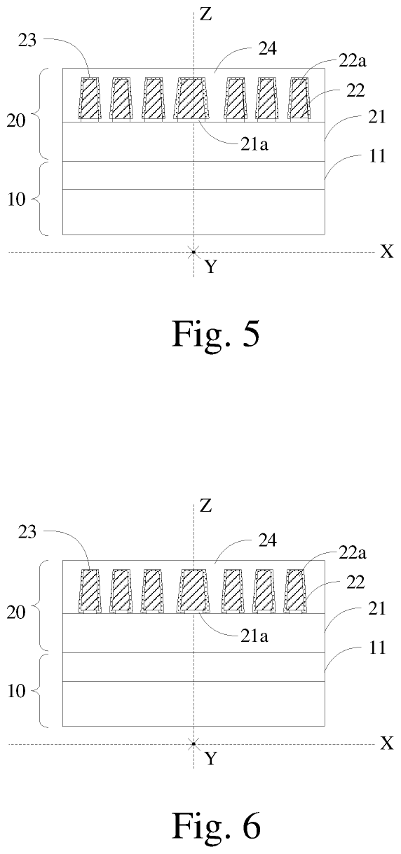

As shown in FIG. 5, which is a structural diagram of a second example of the second semiconductor structure 20. The first semiconductor structure 10 includes a first insulating layer 11, the second semiconductor structure 20 includes a second insulating layer 21, an active layer 22, a gate oxide layer 23 and a gate layer 24, wherein a side of the second insulating layer 21 is bonded with the first insulating layer 11.

The second insulating layer 21 includes at least one protruding portion 21a protruding away from a side of the first semiconductor structure 10, the active layer 22 is disposed on a side of the second insulating layer 21 away from the first semiconductor structure 10, the active layer 22 of the second well region includes at least one fin 22a disposed correspondingly on the at least one protruding portion 21a respectively, a gate oxide layer 23 is disposed on the fin 22a, and a gate layer 24 is disposed on the gate oxide layer 23.

As can be understood, in the etching process, in the process of etching the active layer 22, the second insulating layer 21 would be partially etched to form the protruding portion 21a. Therefore, the protruding portion 21a and the fin 22a formed by etching the active layer 22 are in one-to-one correspondence. In this example, a width of the contact surface between the protruding portion 21a and the fin 22a in X direction is equal to a width of the contact surface between the fin 22a and the protruding portion 21a in X direction.

Referring further to FIG. 6, which is a structural diagram of a third example of the second semiconductor structure 20, the first semiconductor structure 10 includes a first insulating layer 11, the second semiconductor structure 20 includes a second insulating layer 21, an active layer 22, a gate oxide layer 23 and a gate layer 24, wherein a side of the second insulating layer 21 is bonded with the first insulating layer 11.

The second insulating layer 21 includes at least one protruding portion 21a protruding away from a side of the first semiconductor structure 10, the active layer 22 is disposed on a side of the second insulating layer 21 away from the first semiconductor structure 10, the active layer 22 of the second well region includes at least one fin 22a disposed correspondingly on the at least one protruding portion 21a respectively, a gate oxide layer 23 is disposed on the fin 22a, and a gate layer 24 is disposed on the gate oxide layer 23.

In this example, a width of the contact surface between the protruding portion 21a and the fin 22a in X direction is smaller than a width of the contact surface between the fin 22a and the protruding portion 21a in X direction.

As can be understood, in the etching process, in the process of etching the active layer 22, the second insulating layer 21 would be partially etched to form the protruding portion 21a. Further, based on the extent of etching, both sides of the protruding portion 21a in X direction will be etched (side etching) to a certain extent such that the width of the contact surface between the protruding portion 21a and the fin 22a in X direction is smaller than the width of the contact surface between the fin 22a and the protruding portion 21a in X direction.

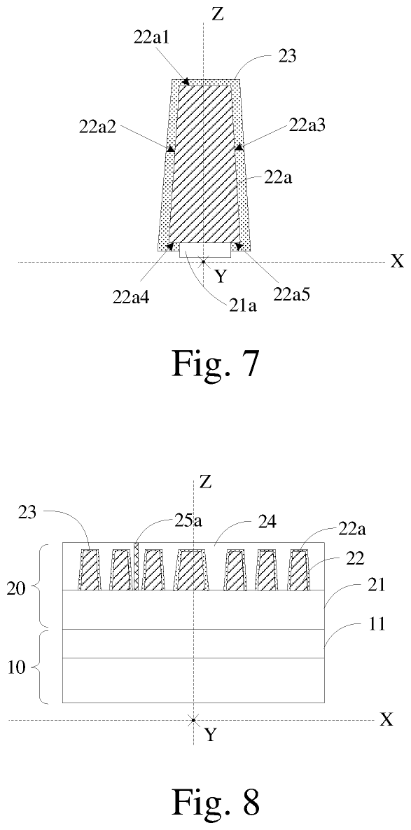

In an example, referring to FIG. 7, which is a partial diagram of the fin in FIG. 6, which is along the thickness direction (Z direction) of the fin 22a, a width of the upper end of the fin 22a in X direction is smaller than a width of the lower end in X direction due to the etch process. Further, the fin 22a includes a top surface 22al and side surfaces (a first side surface 22a2 and a second side surface 22a3). Since side etching would further form bottom surfaces (a first bottom surface 22a4 and a second bottom surface 22a5) of the fin 22a, the bottom surfaces are non-contact surfaces of the fin 22a that suspend beyond the contact surface of the protruding portion 21a. The first side surface 22a2 and the second side surface 22a3 are two side surfaces symmetrical about the YZ plane. The top surface 22al is parallel to the plane where the second insulating layer 21 extends. The first bottom surface 22a4 and the second bottom surface 22a5 are two side surfaces symmetrical about the YZ plane. The side surfaces (the first side surface 22a2 and the second side surface 22a3) connect the top surface 22al and the bottom surfaces. In an example, the first side surface 22a2 connects the top surface 22al and the first bottom surface 22a4 and the second side surface 22a3 connects the top surface 22al and the second bottom surface 22a5. The gate oxide layer 23 covers the top surface 22al, the side surfaces (the first side surface 22a2 and the second side surface 22a3) and the bottom surfaces (the first bottom surface 22a4 and the second bottom surface 22a5).

As can be understood, in this example, by providing the active layer 22 as at least one fin 22a and then covering the top surface, side surfaces and bottom surfaces of the fin 22a with the gate oxide layer 23, the channel of the Fin-FET structure formed as above is mainly formed by high and thin fin projected from the insulating substrate with source and drain on either side thereof and a gate abutting its sidewalls, top and partial bottom for assisting in current control. Such a fin-like structure increases the area of channel surrounded by the gate, enhances the control of the gate to the channel, thereby effectively mitigating the short channel effect in planar devices, significantly improving circuit control and reducing leakage, and greatly reducing gate length of the transistor. Exactly for this characteristic, a Fin-FET does not need a highly doped channel, thereby effectively reducing the impurity ion scattering effect and improving channel carrier mobilities.

In connection with the above-described examples, in an optional example, the fin has a thickness of 30 nm-65 nm in Z direction, and in a further example, the thickness of the fin is 40 nm-55 nm. As can be understood, in an example, since the high voltage well region and the low voltage well region are fabricated on the same active layer, and the active layer is 100 nm thick or so in some examples, then in the process of etching the active layer, not the entire thickness of the active layer would be etched, so the overall thickness of the semiconductor device is relatively large and the process is complex and costly. However, in this example, only an active layer of 30 nm-65 nm needs to be fabricated. As compared to the traditional process, the finally formed semiconductor device has a reduced overall thickness, and the process is simple and the cost is controllable.

In an example, the first well region of the first semiconductor structure 10 is the high voltage well region HV, the second well region of the second semiconductor structure 20 is the low voltage well region (including a low voltage well region LV and a low low voltage well region LLV), the first well region has planar transistors disposed therein, and the second well region has fin field effect transistors disposed therein. A thickness of the gate oxide layer corresponding to the low voltage well region LV is greater than a 20) thickness of the gate oxide layer corresponding to the low low voltage well region LLV. Further, a thickness of the gate oxide layer of the planar transistor in the high voltage well region HV is greater than a thickness of the gate oxide layer of the fin field effect transistor in the low voltage well region LV and the low low voltage well region LLV.

As shown in FIG. 8, which is a structural diagram of a fourth example of the second semiconductor structure 20. The first semiconductor structure 10 includes a first insulating layer 11, and the second semiconductor structure 20 includes a second insulating layer 21, an active layer 22, a gate oxide layer 23, a gate layer 24 and a first isolation structure 25a, wherein a side of the second insulating layer 21 is bonded with the first insulating layer 11.

The active layer 22 is disposed on a side of the second insulating layer 21 away from the first semiconductor structure 10. The active layer 22 of the second well region includes at least one fin 22a on which the gate oxide layer 23 is disposed, and the gate layer 24 is disposed on the gate oxide layer 23. The first isolation structure 25a is configured to isolate the gate layer 24 corresponding to two adjacent fins 22a.

Optionally, the first isolation structure 25a may be disposed according to the functions of the fin field effect transistors in the well region in an example. For example, some of the transistors share a gate, then the gate layers corresponding to these transistors need not to be isolated by the first isolation structure 25a. If two adjacent transistors have different functions and cannot share the same gate, the gate layers corresponding to these two transistors need to be isolated by the first isolation structure 25a.

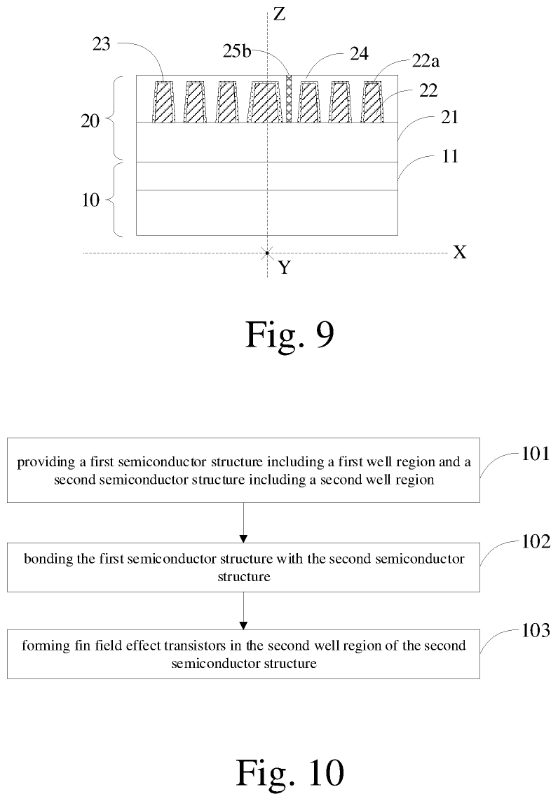

As shown in FIG. 9, which is a structural diagram of a fifth example of the second semiconductor structure 20. The first semiconductor structure 10 includes a first insulating layer 11, and the second semiconductor structure 20 includes a second insulating layer 21, an active layer 22, a gate oxide layer 23, a gate layer 24 and a second isolation structure 25b, wherein a side of the second insulating layer 21 is bonded with the first insulating layer 11.

The active layer 22 is disposed on a side of the second insulating layer 21 away from the first semiconductor structure 10, the active layer 22 of the second well region includes at least one fin 22a on which the gate oxide layer 23 is disposed. The gate layer 24 is disposed on the gate oxide layer 23. The second isolation structure 25b is configured to isolate the gate layer 24 corresponding to different well regions. For example, in an example, the second isolation structure 25b is configured to isolate the low voltage well region (LV) and the low low voltage well region (LLV).

As can be appreciated, in the examples shown in the above-described FIGS. 8 and 9, the positions and shapes of the first isolation structure 25a and the second isolation structure 25b are schematic. In specific scenarios, they may be disposed arbitrarily according to practical demands, which is not limited herein.

The manufacturing process of the above-described semiconductor device will be introduced below.

As shown in FIG. 10, which is a flow chart of an example of a manufacturing method of a semiconductor device provided in the present disclosure, the manufacturing method includes:
step 101: providing a first semiconductor structure including a first well region and a 30) second semiconductor structure including a second well region.

As shown in FIG. 1, optionally, the first semiconductor structure 10 and the second semiconductor structure 20 may be wafers.

In one example, the first well region is a high voltage (HV) well region and the second well region is a low voltage well region. Further, the low voltage well region may further include a first sub-well region and a second sub-well region. The first sub-well region is the LV (Low Voltage) well region, and the second sub-well region is a LLV (Low Low Voltage) well region.

Step 102: bonding the first semiconductor structure with the second semiconductor structure.

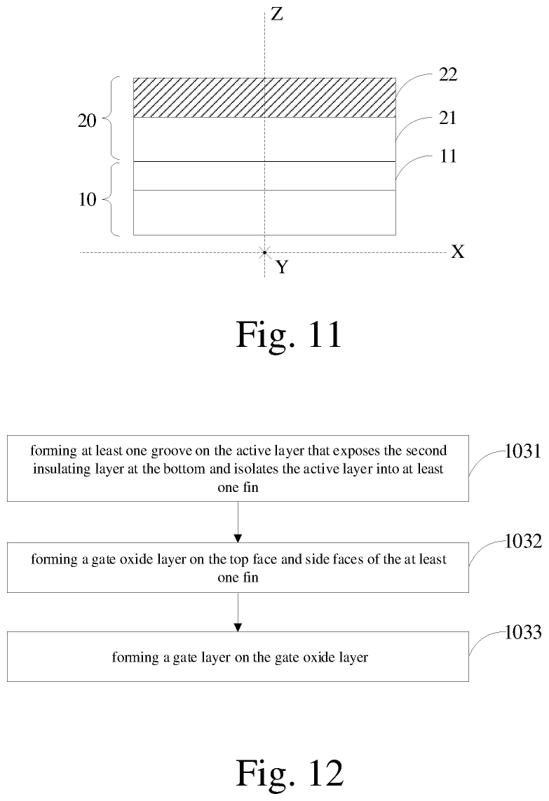

Optionally, in an example, as shown in FIG. 11, which is a structural diagram of an example of step 102 in FIG. 10, the first semiconductor structure 10 includes a first insulating layer 11 and the second semiconductor structure 20 includes an active layer 22. Before bonding the first semiconductor structure 10 with the second semiconductor structure 20, a second insulating layer 21 is formed on the active layer 22, and then a side of the first insulating layer 11 of the first semiconductor structure 10 is bonded with a side of the second insulating layer 21 of the second semiconductor structure 20.

Optionally, the active layer is a layer of thin film on the wafer and made of semiconductor material. The thickness of the active layer is between hundreds of nanometers to tens of nanometers in some examples. The active layer functions to penetrate electronically active substances on the wafer surface into the wafer surface to facilitate fabrication of elements thereon.

The active layer may adopt silicon (single crystalline silicon, poly-crystalline silicon or amorphous silicon), germanium (single crystalline germanium), silicon germanium etc. and may be P-doped or N-doped.

Optionally, the first insulating layer 11 and the second insulating layer 21 may use materials such as silicon nitride and silicon oxide.

Step 103: forming fin field effect transistors in the second well region of the second semiconductor structure.

Optionally, as shown in FIG. 12, which is a flow chart of a first example of step 103 in FIG. 10, the step 103 may include:
step 1031: forming at least one groove on the active layer that exposes the second insulating layer at the bottom and isolates the active layer into at least one fin.

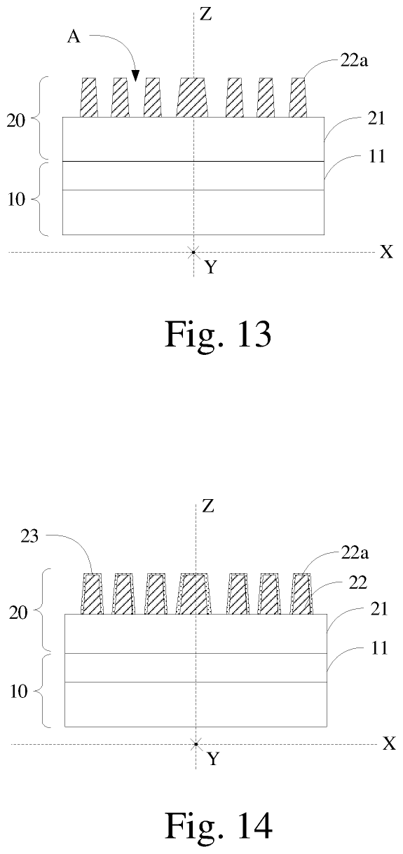

FIG. 13 is a structural diagram of an example of step 1031 in FIG. 12, as shown in FIG. 13, at least one groove A is formed on the active layer 22 that exposes the second insulating layer 21 at the bottom and isolates the active layer 22 into at least one fin 22a.

Optionally, the groove A may be formed with etching process in an example. It is appreciated that due to the etching process, the cross-section of the fin 22a is similar to a trapezoid with narrow top and wide bottom.

Optionally, the fin has a thickness of 30 nm-65 nm in Z direction. Therefore, in an example, if the active layer 22 has a thickness greater than this thickness, the process may further include before the step 1031: thinning the active layer 22.

Step 1032: forming a gate oxide layer on the top surface and side surfaces of the at least one fin.

FIG. 14 is a structural diagram of an example of step 1032 in FIG. 12, as shown in FIG. 14, a gate oxide layer 23 is formed on the at least one fin 22a.

In an example, as shown in FIG. 4, the fin 22a includes a top surface 22al and side surfaces (a first side surface 22a2 and a second side surface 22a3), in which the first side surface 22a2 and the second side surface 22a3 are two side surfaces symmetrical about the YZ plane, the top surface 22al is parallel to the plane where the second insulating layer 21 extends, the side surfaces (the first side surface 22a2 and the second side surface 22a3) are connected with the top surface 22al, and the gate oxide layer 23 covers the top surface 22al and the side surfaces (the first side surface 22a2 and the second side surface 22a3).

Optionally, in an example, step 1032 may be: forming the gate oxide layer 23 on the top surface 22al and the side surfaces (the first side surface 22a2 and the second side surface 22a3) of the at least one fin 22a.

Step 1033: forming a gate layer on the gate oxide layer.

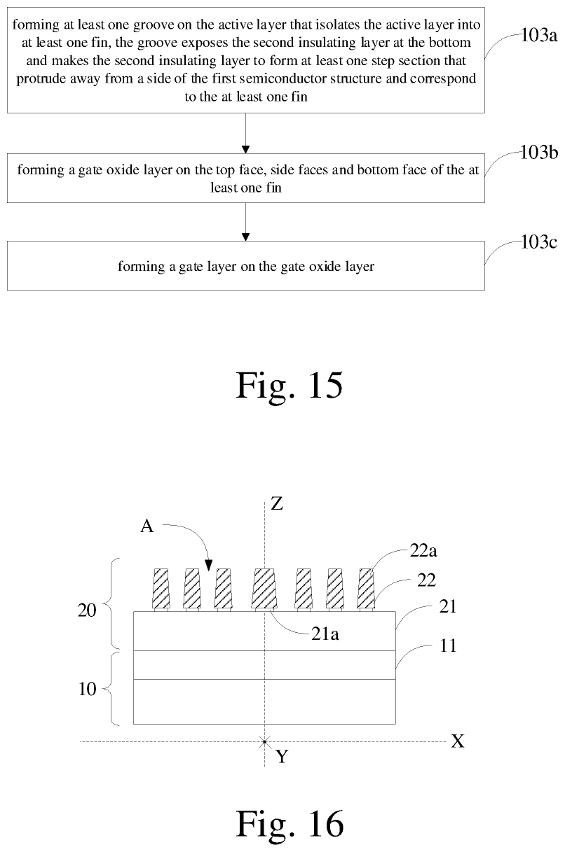

Optionally, as shown in FIG. 15, which is a flow chart of a second example of the step 103 in FIG. 10, the step 103 may include:
step 103a: forming at least one groove on the active layer that isolates the active layer into at least one fin, the groove exposes the second insulating layer at the bottom and makes the second insulating layer to form at least one protruding portion that protrude away from a side of the first semiconductor structure and correspond to the at least one fin.

As shown in FIG. 16, which is a structural diagram of an example of the step 103a in FIG. 15, at least one groove A is formed on the active layer 22 that isolates the active layer 22 into at least one fin 22a, the groove A exposes the second insulating layer 21 at the bottom and makes the second insulating layer 21 to form at least one protruding portion 21a that protrude away from a side of the first semiconductor structure 10 and correspond to the at least one fin 22a.

In this example, a width of a contact surface between the protruding portion 21a and the fin 22a in X direction is smaller than a width of a contact surface between the fin 22a and the protruding portion 21a in X direction.

As can be understood, in the etching process, in the process of etching the active layer 22, the second insulating layer 21 would be partially etched to form the protruding portion 21a. Further, based on the extent of the etching, both sides of the protruding portion 21a in X direction would be etched (side etching) to a certain extent such that the width of the contact surface between the protruding portion 21a and the fin 22a in X direction is smaller than the width of the contact surface between the fin 22a and the protruding portion 21a in X direction.

Step 103b: forming the gate oxide layer on the top surface, the side surfaces and the bottom surface of the at least one fin.

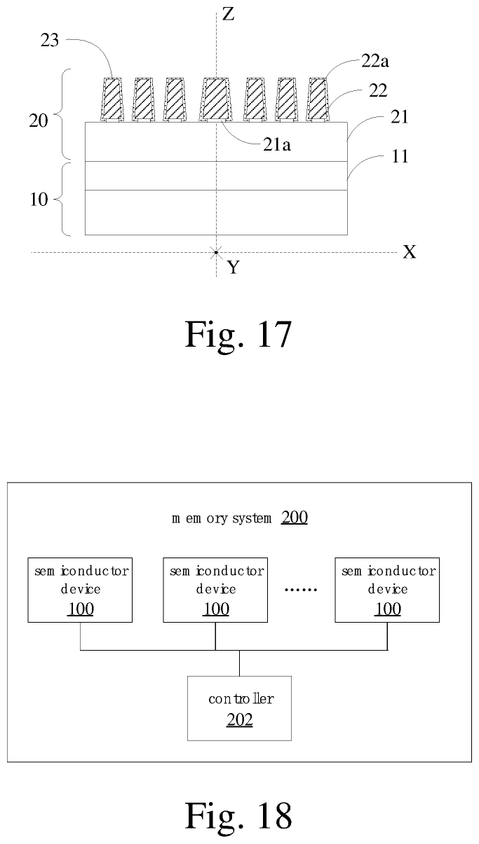

As shown in FIG. 17, which is a structural diagram of an example of the step 103b in FIG. 15.

In an example, as shown in FIG. 7, which is along the thickness direction (Z direction) of the fin 22a, the width of the upper end of the fin 22a in X direction is smaller than the width of the lower end in X direction due to the etch process. Further, the fin 22a includes a top surface 22al and side surfaces (a first side surface 22a2 and a second side surface 22a3). Since the side etching would further form bottom surfaces (a first bottom surface 22a4 and a second bottom surface 22a5) of the fin 22a, the bottom surfaces are non-contact surfaces of the fin 22a that suspend beyond the contact surface of the protruding portion 21a. The first side surface 22a2 and the second side surface 22a3 are two side surfaces symmetrical about the YZ plane. The top surface 22al is parallel to the plane where the second insulating layer 21 extends. The first bottom surface 22a4 and the second bottom surface 22a5 are two side surfaces symmetrical about the YZ plane. The side surfaces (the first side surface 22a2 and the second side surface 22a3) connect the top surface 22al and the bottom surfaces. In an example, the first side surface 22a2 connects the top surface 22al and the first bottom surface 22a4 and the second side surface 22a3 connects the top surface 22al and the second bottom surface 22a5. The gate oxide layer 23 covers the top surface 22al, the side surfaces (the first side surface 22a2 and the second side surface 22a3) and the bottom surfaces (the first bottom surface 22a4 and the second bottom surface 22a5).

Step 103c: forming a gate layer on the gate oxide layer.

Optionally, in an example, steps 1033 and 103c may include: forming a gate layer on the gate oxide layer and the exposed second insulating layer; thinning the gate layer to expose the top surface of the gate oxide layer that is parallel to the plane where the second insulating layer extends.

Optionally, in the examples of the above-described FIGS. 12 and 15, before forming the gate insulating layer 23, it is also possible to form a liner layer on the fin 22a and then remove the liner layer and then perform the step of manufacturing the gate insulating layer 23. Optionally, the liner layer may include dielectric materials such as silicon oxide, silicon nitride and/or other suitable materials. It is appreciated that the liner layer may be a catalyzing layer that facilitates adhering of material of the gate oxide layer that is continually arranged or a blocking layer that may prevent potential contamination of the fin 22a due to the subsequently deposition of isolation materials. For example, the liner layer may be of silicon oxide, silicon nitride, silicon oxynitride, silicon carbide, silicon carbonitride, titanium nitride, tantalum nitride, any suitable material and/or combinations thereof.

Optionally, in an example, it is further possible to form a first isolation structure and a second isolation structure. As shown in FIG. 8, the first isolation structure 25a is formed on the second insulating layer 21 to isolate the gate layer 24 corresponding to two adjacent fins 22a. The first isolation structure 25a penetrates through the gate layer 24 in Z direction.

Optionally, in an example, the first isolation structure 25a may be disposed according to the functions of the fin field effect transistors in the well region. For example, some of the transistors share a gate, then the gate layer corresponding to these transistors need not to be isolated by the first isolation structure 25a. If two adjacent transistors have different functions and cannot share the same gate, the gate layer corresponding to these two transistors need to be isolated by the first isolation structure 25a.

As shown in FIG. 9, the second isolation structure 25b is formed on the gate oxide layer 23 to isolate the gate layer 24 corresponding to different well regions. The second isolation structure 25b penetrates through the gate layer 24 in Z direction.

As can be appreciated, in the examples shown in the above-described FIGS. 8 and 9, the positions and shapes of the first isolation structure 25a and the second isolation structure 25b are schematic. In specific scenarios, they may be disposed arbitrarily according to practical demands, which is not limited herein.

Optionally, as shown in FIG. 2, after completing the manufacture of the fin field effect transistors of the second semiconductor structure 20, it is further possible to bond the memory array structure 30 with the second semiconductor structure 20 to form a 3D memory.

It is appreciated that with the manufacturing process provided in examples of the present disclosure, by manufacturing fin field effect transistors in one of the semiconductor structures after bonding two semiconductor structures, on the one hand, the first well region and the second well region are disposed in the two semiconductor structures such as wafers respectively, and wherein the fin field effect transistors are disposed in the second well region of the second semiconductor structure, as compared to the traditional process in which the two well regions are disposed in the same wafer or the two well regions are disposed on two wafers respectively but without fin field effect transistors, the examples of the present disclosure can improve transistor performance using the fin field effect transistors while reducing the chip area; and on the other hand, as compared to the traditional manufacture of the fin field effect transistors, such a manufacturing process reduces the filling and planarization of shallow trench isolation and also reduces the wet etching process for the isolation trench, resulting in reduced costs and improved manufacturing efficiency.

Referring to FIG. 18, which is a structural diagram of an example of a memory system provided in the present disclosure, the memory system 200 includes at least one semiconductor device 100 and a controller 202. The controller 202 is coupled to the semiconductor device 100 to control the semiconductor device 100 to store data. The memory system 200 may be integrated into various memory cards such as a personal computer card (personal computer memory card international association, PCMCIA or PC), a compact flash (CF) card, a smart media (SM) card, a memory stick, a multimedia card (MMC), a secure digital card (SD), a universal flash storage (UFS) and solid state drives (SSD).

The controller 202 is configured to operate in low duty cycle environment, such as SD cards, CF cards, Universal Serial Bus (USB) flash drives, or other media used in electronic devices such as personal calculators, digital cameras and mobile phones.

Alternatively, the controller 202 is configured to operate in high duty cycle environment SSDs or eMMCs that are used as data stores and enterprise memory arrays of the mobile devices such as smart phones, tablet computers and laptop computers.

Alternatively, the controller 202 is configured to manage data stored in the semiconductor device 100 and communicate with external equipments such as hosts according to particular communication protocols. The communication protocols include at least one of a USB protocol, an MMC protocol, a peripheral component interconnection (PCI) protocol, a PCI-express (peripheral component interconnect express, PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a Firewire protocol.

The controller 202 can be further configured to control operations of the semiconductor device 100, such as read, erase, and program operations. In some examples, the controller 202 can also be configured to manage various functions with respect to the data stored or to be stored in the semiconductor device 100, including, but not limited to at least one of bad-block management, garbage collection, logical-to-physical address conversion, wear leveling, etc. In some examples, the controller 202 is further configured to handle error correction codes with respect to data read from or written into the semiconductor device 100. The controller 202 may further execute any other suitable functions such as formatting the semiconductor device 100.

Optionally, the semiconductor device 100 in this example is the semiconductor device 100 as introduced in the above-described examples or the semiconductor device 100 manufactured by the manufacturing method as introduced in the above-described examples. In an example, the semiconductor device 100 is a 3D memory device.

The examples of the present disclosure have been described in detail above. Specific examples are used herein to set forth the principle and implementations of the present disclosure and description of the above examples is only for assisting understanding the method and gist thereof of the present disclosure. Meanwhile, those skilled in the art may make modifications to implementations and disclosure ranges according to the idea of the present disclosure. In summary, the contents of the present specification should not be construed as limiting the present disclosure.

What is claimed is:

1. A semiconductor device, comprising:
a first semiconductor structure comprising:
a first well region, and
transistors in the first well region; and
a second semiconductor structure bonded with the first semiconductor structure and comprising:
a second well region, and
fin field effect transistors in the second well region, each fin field effect transistor comprising:
a fin structure;
a gate oxide layer in contact with a top surface and side surfaces of the fin structure, and
a gate layer covering the gate oxide layer.

2. The semiconductor device of claim 1, wherein:
the first semiconductor structure comprises a first insulating layer; and
the second semiconductor structure comprises a second insulating layer;
wherein:
a first surface of the second insulating layer is bonded with the first insulating layer,
a second surface of the second insulating layer opposite to the first surface comprises protruding portions, and
each fin structure is located on a top surface of a corresponding protruding portion.

3. The semiconductor device of claim 1, wherein:
the fin has a thickness between 30 nm and 65 nm in a vertical direction perpendicular to a bonding interface between the first semiconductor structure and the second semiconductor structure.

4. The semiconductor device of claim 2, wherein:
the gate oxide layer is further in contact with portions of a bottom surface of the fin structure.

5. The semiconductor device of claim 2, wherein,
a contact interface between the protruding portion and the fin structure is less than a bottom surface of the fin structure.

6. The semiconductor device of claim 1, wherein:
a thickness of a gate oxide layer of the transistors in the first well region is greater than a thickness of the gate oxide layer of the fin field effect transistors in the second well region.

7. The semiconductor device of claim 1, wherein:
the second well region comprises a first sub-well region and a second sub-well region; and
a thickness of the gate oxide layer in the first sub-well region is greater than a thickness of the gate oxide layer in the second sub-well region.

8. The semiconductor device of claim 2, wherein the second semiconductor structure further comprises:
a first isolation structure configured to isolate two portions of the gate layer corresponding to two adjacent fin structures.

9. The semiconductor device of claim 7, wherein the second semiconductor structure further comprises:
a second isolation structure configured to isolate two portions of the gate layer corresponding to the first sub-well region and the second sub-well region, respectively.

10. The semiconductor device of claim 1, further comprising:
a memory array structure bonded with the second semiconductor structure.

11. A method of forming a semiconductor device, comprising:
forming a first semiconductor structure comprising a first well region and transistors in the first well region;
forming a second semiconductor structure comprising a second well region;
bonding the first semiconductor structure with the second semiconductor structure; and
forming fin field effect transistors in the second well region, wherein each fin field effect transistor comprises a fin structure, a gate oxide layer in contact with a top surface and side surfaces of the fin structure, and a gate layer covering the gate oxide layer.

12. The method of claim 11, wherein:
forming the first semiconductor structure comprises forming a first insulating layer;
forming the second semiconductor structure comprises:
forming a second insulating layer,
forming an active layer on the second insulating layer, and
forming the fin structures in the active layer; and
bonding the first semiconductor structure with the second semiconductor structure comprises boning the first insulating layer to the second insulating layer.

13. The method of claim 12, wherein forming the fin field effect transistors comprises:
forming grooves in the active layer to separate the active layer into the fin structures;
forming the gate oxide layer to cover the top surfaces and the side surfaces of the fin structures; and
forming a gate layer to cover the gate oxide layer.

14. The method of claim 13, further comprising:
before forming the grooves, thinning the active layer;
before forming the gate oxide layer, forming a liner layer to cover the fin structures; and
removing the liner layer.

15. The method of claim 13, wherein forming the grooves comprises:
removing portions of the active layer to expose the second insulating layer and separate the active layer into the fin structures; and
removing portions of the expose second insulating layer to form protruding portions each under and in contact with one corresponding fin structure.

16. The method of claim 13, wherein:
removing portions of the expose second insulating layer comprises removing portions of the second insulating layer under the fin structures, such that a contact interface between one protruding portion and one corresponding fin structure is less than a bottom surface of the corresponding fin structure; and
forming the gate oxide layer comprises forming the gate oxide layer to further cover portions of the bottom surfaces of the fin structures.

17. The method of claim 16, wherein forming the gate layer comprises:
forming the gate layer to cover the gate oxide layer and the exposed second insulating layer; and
thinning the gate layer to expose top surfaces of the gate oxide layer.

18. The method of claim 16, further comprising:
forming a first isolation structure on the second insulating layer to isolate portions of the gate layer corresponding to two adjacent fin structures; and
forming a second isolation structure on the gate oxide layer to isolate portions of the gate layer corresponding to different sub-well regions.

19. The method of claim 11, further comprising:
forming a memory array structure; and
bonding the memory array structure with the second semiconductor structure.

20. A memory system, comprising:
a memory device, comprising:
a first semiconductor structure comprising a first well region and transistors in the first well region, and
a second semiconductor structure bonded with the first semiconductor structure and comprising a second well region, and fin field effect transistors in the second well region;
wherein each fin field effect transistor comprises a fin structure, a gate oxide layer in contact with a top surface and side surfaces of the fin structure, and a gate layer covering the gate oxide layer; and
a controller coupled to the memory device to control the memory device to store data.
